(19) United States
(12) Patent Application Publication
(10) Pub. No.: US 2026/0088116 A1
(43) Pub. Date: Mar. 26, 2026

(54) MEMORY DEVICE PERFORMING ERASE OPERATION IN SUB-BLOCK UNIT AND OPERATING METHOD OF MEMORY DEVICE

(71) Applicant: SK hynix Inc., Gyeonggi-do (KR)

(72) Inventor: Jae Wook YANG, Gyeonggi-do (KR)

(21) Appl. No.: 19/052,292

(22) Filed: Feb. 13, 2025

(30) Foreign Application Priority Data
Sep. 25, 2024 (KR) 10-2024-0130027

(51) Int. Cl. G11C 29/12; G11C 29/14; G11C 29/18

(52) U.S. Cl. CPC G11C 29/1201; G11C 29/14; G11C 29/18; G11C 2029/1802

(57) ABSTRACT

A memory device includes a plurality of memory blocks each including first and second sub-blocks, and a control circuit. The control circuit may apply a first erase permission voltage and a first erase voltage among a plurality of erase voltages to a first sub-block of a selected memory block, and check a level of the first erase voltage applied when a verification of an erase state of the first sub-block is successful, apply a second erase permission voltage and a second erase voltage among the plurality of erase voltages to a second sub-block of the selected memory block, and check a level of the second erase voltage applied when a verification of an erase state of the second sub-block is successful, and adjust levels of the first and second erase permission voltages based on a result of a comparison between the levels of the first and second erase voltages.

### CROSS-REFERENCE TO RELATED APPLICATION

This application claims priority under 35 U.S.C. § 119(a) to Korean Patent Application No. 10-2024-0130027, filed on Sep. 25, 2024, the entire contents of which are incorporated herein by reference.

### BACKGROUND

### 1. Field

Embodiments of the present disclosure relate to a semiconductor design technology, and particularly, to a memory device and an operating method of the memory device.

### 2. Discussion of the Related Art

Memory systems are storage devices embodied using a semiconductor such as silicon (Si), germanium (Ge), gallium arsenide (GaAs), indium phosphide (InP), or the like. The memory systems are classified into a volatile memory device and a nonvolatile memory device. The volatile memory device is a memory device in which data stored therein is lost when power supply is interrupted. Representative examples of the volatile memory device include static RAM (SRAM), dynamic RAM (DRAM), synchronous DRAM (SDRAM), etc. The nonvolatile memory device is a memory device in which data stored therein is retained even when power supply is interrupted. Representative examples of the nonvolatile memory device include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. Flash memories are chiefly classified into a NOR-type memory and NAND-type memory.

In order to increase the degree of integration of semiconductor memory devices, a semiconductor memory device having a three-dimensional array structure is researched. In order to efficiently manage a memory block greater than a conventional memory block having a two-dimensional array structure, a technique that manages a memory operation in a sub-block unit is proposed. That is, a semiconductor memory device is proposed which is capable of supporting a partial erase operation of performing an erase operation in a sub-block unit.

Although a partial erase operation is performed in a sub-block unit as described above, in general, an erase operation is performed on at least two sub-blocks having different stack locations from a substrate in the same condition.

For this reason, there is a concern in that data reliability is degraded because the data of a sub-block not selected as an erase target is degraded due to an erase operation that is performed on a sub-block selected as the erase target, among at least two sub-blocks having different stack locations from the substrate.

### SUMMARY

Various embodiments of the present disclosure are directed to a memory device capable of being erased in a sub-block unit and improving memory efficiency and the reliability of an erase operation and an operating method of the memory device.

Technical objects to be achieved by the embodiments of the present disclosure are not limited to the aforementioned object, and the other objects not described above may be evidently understood from the following description by a person having ordinary knowledge in the art to which the present disclosure pertains.

In accordance with an embodiment of the present disclosure, a memory device may include a plurality of memory blocks each including first and second sub-blocks; and a control circuit configured to: apply a first erase permission voltage and a first erase voltage among a plurality of erase voltages to a first sub-block of a selected memory block among the plurality of memory blocks, and check a level of the first erase voltage applied when a verification of an erase state of the first sub-block is successful, apply a second erase permission voltage and a second erase voltage among the plurality of erase voltages to a second sub-block of the selected memory block, and check a level of the second erase voltage applied when a verification of an erase state of the second sub-block is successful, and adjust levels of the first and second erase permission voltages based on a result of a comparison between the levels of the first and second erase voltages.

In accordance with an embodiment of the present disclosure, an operating method of a memory device including a plurality of memory blocks each including first and second sub-blocks, the operating method may include: applying a first erase permission voltage and a first erase voltage among a plurality of erase voltages to a first sub-block of a selected memory block among a plurality of memory blocks, and checking a level of the first erase voltage applied when a verification of an erase state of the first sub-block is successful; applying a second erase permission voltage and a second erase voltage among the plurality of erase voltages to a second sub-block of the selected memory block and then checking a level of the second erase voltage applied when a verification of an erase state of the second sub-block is successful; and adjusting levels of the first and second erase permission voltages based on a result of a comparison between the levels of the first and second erase voltages.

According to embodiments of the present disclosure, the memory device capable of performing an erase operation in a sub-block unit can properly adjust a difference between an erase permission voltage and an erase voltage that are supplied to a sub-block depending on the location where the sub-block is stacked over a substrate.

Accordingly, it is possible to improve memory efficiency and the reliability of an erase operation.

### BRIEF DESCRIPTION OF THE DRAWINGS

FIG. 1 is a diagram for describing an example of a memory system including a memory device according to an embodiment of the present disclosure.

FIG. 2 is a diagram for describing a memory device according to an embodiment of the present disclosure which is connected to an external device for a test operation.

FIG. 3 is a diagram for describing detailed components of the memory device according to an embodiment of the present disclosure.

FIGS. 4A and 4B are flowcharts for describing an erase operation that is performed in the memory device according to an embodiment of the present disclosure.

FIG. 5 is a diagram for describing detailed components of a memory block included in the memory device according to an embodiment of the present disclosure.

FIGS. 6A to 6D are diagrams for describing an erase operation that is performed in a sub-block unit in the memory device according to an embodiment of the present disclosure.

FIGS. 7A to 7C are timing diagrams for describing an erase operation that is performed in the memory device according to an embodiment of the present disclosure.

### DETAILED DESCRIPTION

Various embodiments of the present disclosure are described below with reference to the accompanying drawings. Elements and features of the present disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language includes hardware, for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that implement or perform one or more tasks.

As used in the present disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or a portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that the terms precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. For example, the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

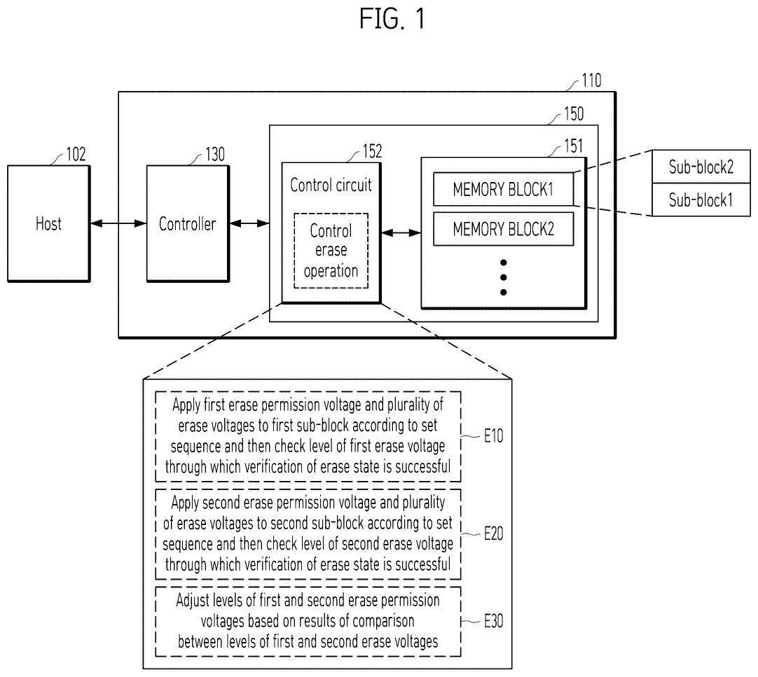

FIG. 1 is a diagram for describing a memory system including a memory device according to an embodiment of the present disclosure.

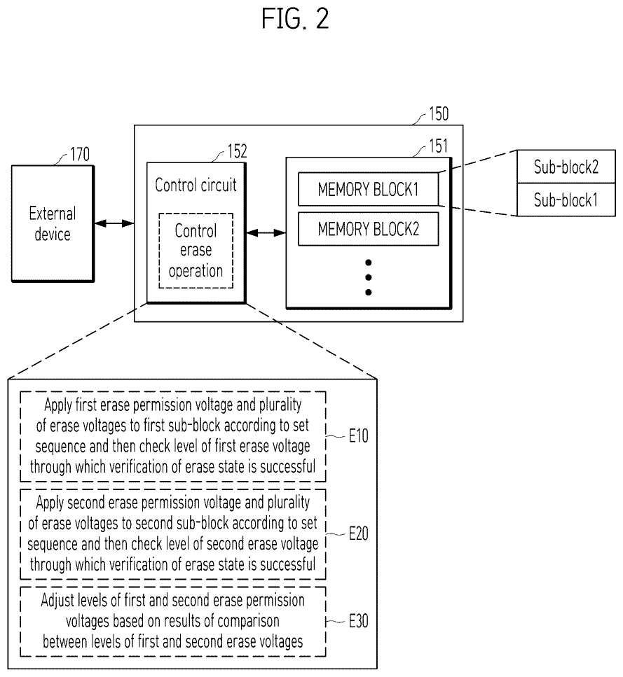

FIG. 2 is a diagram for describing a memory device according to an embodiment of the present disclosure which is connected to an external device for a test operation.

Referring to FIG. 1, the data processing system 100 may include a host 102 engaged or coupled with a memory system, such as memory system 110. For example, the host 102 and the memory system 110 can be coupled to each other via a data bus, a host cable and the like to perform data communication.

The memory system 110 may include a memory device 150 and a controller 130. The memory device 150 and the controller 130 in the memory system 110 may be considered components or elements physically separated from each other. The memory device 150 and the controller 130 may be connected via at least one data path. For example, the data path may include a channel and/or a way.

According to an embodiment, the memory device 150 and the controller 130 may be components or elements functionally divided. Further, according to an embodiment, the memory device 150 and the controller 130 may be implemented with a single chip or a plurality of chips. The controller 130 may perform a data input/output operation in response to a request input from the external device. For example, when the controller 130 performs a read operation in response to a read request input from an external device, data stored in a plurality of non-volatile memory cells included in the memory device 150 is transferred to the controller 130.

For example, the memory system 110 may be implemented with any of various types of storage devices, which may be electrically coupled with the host 102, according to a protocol of a host interface. Non-limiting examples of suitable storage devices include a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like.

The controller 130 may control the memory device 150 to perform read, program and erase operations corresponding to commands inputted from the host 102, and the memory system 110 may independently perform the operations regardless of commands inputted from an external device such as the host 102.

In an embodiment, the controller 130 may autonomously generate a command, an address, and data regardless of a request from the host 102, and may transmit the command, the address, and the data to the memory device 150. For example, the controller 130 may provide commands, addresses, and data to the memory device 150 so as to perform background operations, such as a read operation and a program operation for wear leveling, garbage collection, read reclaim, and media scan.

In an embodiment, the memory device 150 may take many alternative forms, such as a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus dynamic random access memory (RDRAM), a NAND flash memory, a vertical NAND flash memory, a NOR flash memory device, a resistive RAM (RRAM), a phase-change memory (PRAM), a magnetoresistive RAM (MRAM), a ferroelectric RAM (FRAM), or a spin transfer torque RAM (STT-RAM).

More specifically, the memory device 150 may include a memory cell array 151 in which data are stored and a control circuit 152 that controls an operation of the memory cell array 151.

The memory cell array 151 may include a plurality of memory blocks MEMORY BLOCK<1, 2, . . . >. Furthermore, each of the plurality of memory blocks MEMORY BLOCK<1, 2, . . . > may include a plurality of pages (not illustrated).

The memory blocks may be understood as a group of non-volatile memory cells from which data are removed together through the erase operation. Each of the memory blocks may include a page (not illustrated) in which the non-volatile memory cells are grouped, from a logical point of view, such as storing of data together during the program operation or outputting of data together during the read operation. For example, one memory block may include a plurality of pages. One page may include a plurality of non-volatile memory cells.

From a physical point of view different from the logical point of view such as the program operation or the read operation, one memory block may include a plurality of word lines (not illustrated). One word line may include a plurality of non-volatile memory cells.

In this case, one word line may correspond to at least one page according to the number of bits that can be stored or expressed in one non-volatile memory cell. For example, when one non-volatile memory cell is a single level cell (SLC) storing one data bit, one word line may correspond to one page. When one non-volatile memory cell is a double level cell (DLC) storing two data bits, one word line may correspond to two pages. When one non-volatile memory cell is a triple level cell (TLC) storing three data bits, one word line may correspond to three pages. When one non-volatile memory cell is a quadruple level cell (QLC) storing four data bits, one word line may correspond to four pages. In this way, when one non-volatile memory cell is a multiple level cell storing five or more data bits, one word line may correspond to five or more pages.

Each of the plurality of memory blocks MEMORY BLOCK<1, 2, . . . > may include two or more sub-blocks which may be independently erased. That is, in general, one memory block is set as a group of memory cells which may be erased once through an erase operation. However, in an embodiment of the present disclosure, two or more sub-blocks included in each of the plurality of memory blocks may be set as a group of memory cells which may be erased once through an erase operation. In this case, each of the two or more sub-blocks included in each of the plurality of memory blocks may include a plurality of cell strings. Each of the plurality of cell strings may include a plurality of memory cells stacked over a substrate.

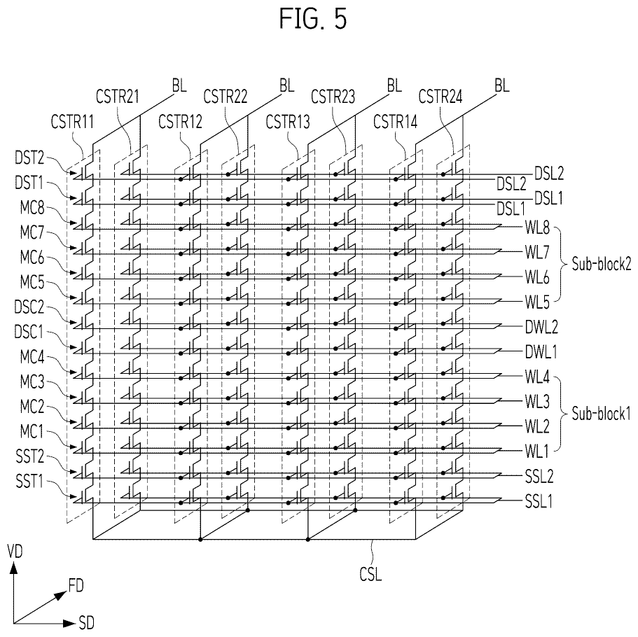

Referring to FIG. 5 along with FIG. 1, each of the plurality of memory blocks MEMORY BLOCK<1, 2, . . . > may include a plurality of cell strings CSTR11 to CSTR24 that is connected between a plurality of bit lines BL and a common source line CSL. The plurality of cell strings CSTR11 to CSTR24 may be constructed identically.

Each of the plurality of cell strings CSTR11 to CSTR24 may be connected between the bit line BL associated with each cell string and the common source line CSL.

Each of the plurality of cell strings CSTR11 to CSTR24 may include a plurality of drain selection transistors DST<1:2>, a plurality of memory cells MC<1:8>, a plurality of dummy memory cells DSC<1:2>, and a plurality of source selection transistors SST<1:2> which are connected between the bit line BL associated with each cell string and the common source line CSL in series. The plurality of memory cells MC<1:8> denotes memory cells that are used to store valid data. The plurality of dummy memory cells DSC<1:2> denotes memory cells that are not used to store valid data.

The plurality of source selection transistors SST<1:2>, the plurality of memory cells MC<1:8>, the plurality of dummy memory cells DSC<1:2>, and the plurality of drain selection transistors DST<1:2> may be sequentially disposed in a height direction VD. In this case, the plurality of dummy memory cells DSC<1:2> may be disposed in the middle of the plurality of memory cells MC<1:8>. For example, as in FIG. 5, the plurality of dummy memory cells DSC<1:2> may be disposed between first to fourth memory cells MC<1:4> and fifth to eighth memory cells MC<5:8>.

Gates of the plurality of source selection transistors SST<1:2> may be connected to a plurality of source selection lines SSL<1:2>, respectively. Gates of the plurality of memory cells MC<1:8> may be connected to a plurality of word lines WL<1:8>, respectively. Gates of the plurality of dummy memory cells DSC<1:2> may be connected to a plurality of dummy word lines DWL<1:2>, respectively. Gates of the plurality of drain selection transistors DST<1:2> may be connected to a plurality of drain selection lines DSL<1:2>, respectively.

The common source line CSL may be formed in a substrate (not illustrated). The substrate may have a main surface that extends in a first direction FD and a second direction SD. The common source line CSL may extend in the second direction SD. The first direction FD and the second direction SD may be directions that are orthogonal to each other.

The bit line BL may extend in the first direction FD, and may be disposed in the second direction SD. the plurality of source selection lines SSL<1:2>, the plurality of word lines WL<1:8>, the plurality of dummy word lines DWL<1:2>, and the plurality of drain selection lines DSL<1:2> may extend in the second direction SD.

The plurality of cell strings CSTR11 to CSTR24 may extend in the height direction VD that is perpendicular to the main surface of the substrate, and may be arranged in the first direction FD and the second direction SD. In each of the plurality of cell strings CSTR11 to CSTR24, the height of the memory cell MC<1> that is closest to the plurality of source selection transistors SST<1:2> may be the lowest, and the height of the memory cell MC<8> that is closest to the plurality of drain selection transistors DST<1:2> may be the highest.

FIG. 5 illustrates that two drain selection transistors DST<1:2> and two source selection transistors SST<1:2> are provided in each of the plurality of cell strings CSTR11 to CSTR24. However, at least one drain selection transistor or at least one source selection transistor may be provided in each of the plurality of cell strings CSTR11 to CSTR24.

FIG. 5 illustrates that each of the plurality of cell strings CSTR11 to CSTR24 includes eight main memory cells MC<1:8>. However, at least two memory cells may be provided in each of the plurality of cell strings CSTR11 to CSTR24.

FIG. 5 illustrates that each of the plurality of cell strings CSTR11 to CSTR24 includes two dummy memory cells DSC<1:2> which are provided between four main memory cells MC<1:4> and the remaining four memory cells MC<5:8>. However, each of the plurality of cell strings CSTR11 to CSTR24 may include one or more dummy memory cells.

Each of the plurality of memory blocks MEMORY BLOCK<1, 2, . . . > may include a first sub-block Sub-block1 and a second sub-block Sub-block2. The first sub-block Sub-block1 may include first to fourth word lines WL<1:4>. The second sub-block Sub-block2 may include fifth to eighth word lines WL<5:8>. In this case, the first sub-block Sub-block1 and the second sub-block Sub-block2 may be disposed in the height direction VD. That is, the first to fourth word lines WL<1:4> that are stacked on one side of the two dummy word lines DWL<1:2> used as reference word lines may be set as the first sub-block Sub-block1. The fifth to eighth word lines WL<5:8> that are stacked on the other side of the two dummy word lines DWL<1:2> used as reference word lines may be set as the second sub-block Sub-block2.

The first sub-block Sub-block1 and the second sub-block Sub-block2 may be independently erased. That is, any sub-block of the first sub-block Sub-block1 and the second sub-block Sub-block2 may be selected, an erase operation may be performed on the selected sub-block, and an erase operation might not be performed on the unselected sub-block. In this case, erase prevention voltages may be driven in the two dummy word lines DWL<1:2> disposed between the first to fourth word lines WL<1:4> and the fifth to eighth word lines WL<5:8> in order to independently erase the first sub-block Sub-block1 and the second sub-block Sub-block2. Furthermore, the levels of the erase prevention voltages that are driven in the two dummy word lines DWL<1:2>, respectively, may be different from each other.

A method of dividing sub-blocks defined within each of the plurality of memory blocks MEMORY BLOCK<1, 2, . . . > has been described as an embodiment. However, a criterion for dividing sub-blocks is not limited to only the embodiment. That is, an embodiment in which each of the plurality of memory blocks MEMORY BLOCK<1, 2, . . . > includes the two sub-blocks Sub-block1 and Sub-block2 has been described, but each of the plurality of memory blocks MEMORY BLOCK<1, 2, . . . > may include three or more sub-blocks. Furthermore, an embodiment in which four word lines are included in one sub-block (i.e., Sub-block1 or Sub-block2) has been described, but it may be well understood that one sub-block (i.e., Sub-block1 or Sub-block2) may include three or less or five or more word lines. Furthermore, in order to divide the two sub-blocks Sub-block1 and Sub-block2, an embodiment in which the two dummy word lines DWL<1:2> are included has been described, but it may be well understood that one or three or more dummy word lines may be included.

The control circuit 152 may control a program operation of storing data in the memory cell array 151, a read operation of outputting data stored in the memory cell array 151, and an erase operation of erasing data stored in the memory cell array 151 under the control of the controller 130.

The control circuit 152 may divide the first to fourth word lines WL<1:4> stacked on one side of the plurality of dummy word lines DWL<1:2> that is disposed in the middle, among the plurality of word lines WL<1:8> included in each of the plurality of memory blocks MEMORY BLOCK<1, 2, . . . >, as the first sub-block Sub-block1, and may divide the fifth to eighth word lines WL<5:8> stacked on the other side of the plurality of dummy word lines DWL<1:2> as the second sub-block Sub-block2. That is, the reason why at least two sub-blocks may be included in each of the plurality of memory blocks MEMORY BLOCK <1, 2, . . . > may be that the control circuit 152 controls operations by dividing each of the plurality of memory blocks MEMORY BLOCK<1, 2, . . . > into at least two sub-blocks.

The control circuit 152 may perform an erase operation by applying an erase voltage to the substrate corresponding to a selected memory block, among the plurality of memory blocks MEMORY BLOCK<1, 2, . . . >. That is, the control circuit 152 may perform the erase operation by applying the erase voltage to the common source line CSL of the selected memory block. In this case, when performing the erase operation by applying the erase voltage to the substrate corresponding to the selected memory block, the control circuit 152 may select one of the first sub-block Sub-block1 and the second sub-block Sub-block2 included in the selected memory block, and may then perform an independent erase operation on only the selected sub-block. For example, when the first sub-block Sub-block1 is selected as an erase target and the second sub-block Sub-block2 is not selected as the erase target, the control circuit 152 may perform an erase operation on only the first sub-block Sub-block1, and might not perform an erase operation on the second sub-block Sub-block2.

For reference, an operation of erasing a memory cell in a program state through a method of raising the voltage level of a channel of a selected memory block by applying an erase voltage to the substrate corresponding to the selected memory block may be defined as an erase operation using a gate-induced drain leakage (GIDL) method. That is, in the erase operation using the GIDL method, electrons stored in the charge storage layer of the memory cell in the program state, among a plurality of memory cells included in the selected memory block, may be detrapped by a high voltage level of the channel and a low voltage level of a word line. Accordingly, the state of the memory cell in the program state may transition to an erase state.

More specifically, in order to perform a first erase progress operation on the first sub-block Sub-block1 of a selected memory block, among the plurality of memory blocks MEMORY BLOCK<1, 2, . . . >, the control circuit 152 may apply a first erase permission voltage and any of a plurality of erase voltages to the first sub-block Sub-block1 of the selected memory block in a set sequence (E10). According to an embodiment, the control circuit 152 may perform the first erase progress operation by applying any of the plurality of erase voltages to the substrate corresponding to the selected memory block in a set sequence and applying an erase prevention voltage to the fifth to eighth word lines WL<5:8> corresponding to the second sub-block Sub-block2 of the selected memory block, in the state in which the first erase permission voltage has been applied to the first to fourth word lines WL<1:4> corresponding to the first sub-block Sub-block1 of the selected memory block.

Furthermore, after performing the first erase progress operation on the first sub-block Sub-block1 of the selected memory block, the control circuit 152 may check whether the verification of the erase state of the first sub-block Sub-block1 is successful by performing a first erase verification operation (E10). According to an embodiment, the control circuit 152 may perform the first erase verification operation by applying an erase verification voltage to the first to fourth word lines WL<1:4> corresponding to the first sub-block Sub-block1 of the selected memory block. In this case, the erase verification voltage may be a hard erase verification (HEV) voltage. In this case, the HEV voltage may mean a read voltage that determines a distribution of the threshold voltages of memory cells included in an erased memory block.

Furthermore, the control circuit 152 may increase the voltage level of the erase voltage according to an incremental step pulse erase (ISPE) method while alternately performing the first erase progress operation and the first erase verification operation on the first sub-block Sub-block1 of the selected memory block (E10).

Furthermore, when the verification of the erase state is successful in the first erase verification operation, the control circuit 152 may set the erase voltage that was used in the first erase progress operation that had been performed right before, that is, any of the plurality of erase voltages, as a first erase voltage (E10).

Furthermore, if the verification of the erase state is not successful in the first erase verification operation even after the first erase progress operation and the first erase verification operation are alternately performed by a preset number, the control circuit 152 may determine that the erase operation for the first sub-block Sub-block1 has failed. Furthermore, the control circuit 152 may apply a second erase permission voltage and any of the plurality of erase voltages to the second sub-block Sub-block2 of the selected memory block, the plurality of memory blocks MEMORY BLOCK <1, 2, . . . >, in a set sequence in order to perform a second erase progress operation on the second sub-block Sub-block2 of the selected memory block (E20). According to an embodiment, the control circuit 152 may perform the second erase progress operation by applying any of the plurality of erase voltages to the substrate corresponding to the selected memory block in a set sequence and applying an erase prevention voltage to the first to fourth word lines WL<1:4> corresponding to the first sub-block Sub-block1 of the selected memory block, in the state in which the second erase permission voltage has been applied to the fifth to eighth word lines WL<5:8> corresponding to the second sub-block Sub-block2 of the selected memory block.

Furthermore, after performing the second erase progress operation, that is, an erase operation for the second sub-block Sub-block2 of the selected memory block, the control circuit 152 may check whether the verification of the erase state of the second sub-block Sub-block2 is successful by performing a second erase verification operation (E20). According to an embodiment, the control circuit 152 may perform the second erase verification operation by applying an erase verification voltage to the fifth to eighth word lines WL<5:8> corresponding to the second sub-block Sub-block2 of the selected memory block. In this case, the erase verification voltage may be an HEV voltage. In this case, the HEV voltage may mean a read voltage that determines a distribution of the threshold voltages of memory cells included in an erased memory block. That is, the control circuit 152 may use the same erase verification voltage in the first erase verification operation for the first sub-block Sub-block1 of the selected memory block and the second erase verification operation for the second sub-block Sub-block2 of the selected memory block.

Furthermore, the control circuit 152 may increase the voltage level of the erase voltage according to the ISPE method while alternately performing the second erase progress operation and the second erase verification operation on the second sub-block Sub-block2 of the selected memory block (E20).

Furthermore, when the verification of the erase state is successful in the second erase verification operation, the control circuit 152 may set the erase voltage that was used in the second erase progress operation that had been performed right before, that is, any of the plurality of erase voltages as a second erase voltage (E20).

Furthermore, if the verification of the erase state is not successful in the second erase verification operation even after the second erase progress operation and the second erase verification operation are alternately performed by a preset number, the control circuit 152 may determine that the erase operation for the second sub-block Sub-block2 has failed.

The control circuit 152 may set the level of the first erase voltage by repeatedly performing the first erase progress operation and the first erase verification operation on the first sub-block Sub-block1 of the selected memory block as in operation E10, and may set the level of the second erase voltage by repeatedly performing the second erase progress operation and the second erase verification operation on the second sub-block Sub-block2 of the selected memory block as in operation E20.

Thereafter, the control circuit 152 may compare the level of the first erase voltage and the level of the second erase voltage, and may adjust the level of the first erase permission voltage and the level of the second erase permission voltage based on the results of the comparison (E30).

That is, the control circuit 152 may adjust the level of the first erase permission voltage and the level of the second erase permission voltage to be used in operation E10 and operation E20 that are subsequently performed, by performing operation E30 with reference to the level of the first erase voltage used in the first erase progress operation included in operation E10 and the level of the second erase voltage used in the second erase progress operation included in operation E20. Accordingly, if the control circuit 152 performs operation E10 and operation E20 after performing operation E30, the control circuit 152 may use the first erase permission voltage and the second erase permission voltage having the levels adjusted in operation E30 that was performed before.

According to an embodiment, the control circuit 152 may adjust the level of the first erase permission voltage and the level of the second erase permission voltage, by performing operation E10 on the first sub-block Sub-block1 of a No. 1 memory block MEMORY BLOCK1, among the plurality of memory blocks MEMORY BLOCK<1, 2, . . . >, by using the first erase permission voltage having a default level, performing operation E20 on the second sub-block Sub-block2 of the No. 1 memory block MEMORY BLOCK1 by using the second erase permission voltage having a default level, and then performing operation E30.

Thereafter, when performing operation E10 on the first sub-block Sub-block1 of a No. 2 memory block MEMORY BLOCK2, among the plurality of memory blocks MEMORY BLOCK<1, 2, . . . >, the control circuit 152 may use the first erase permission voltage having the level adjusted in operation E30 that was performed before. Likewise, when performing operation E20 on the second sub-block Sub-block2 of the No. 2 memory block MEMORY BLOCK2, the control circuit 152 may use the second erase permission voltage having the level adjusted in operation E30 that was performed before.

More specifically, the control circuit 152 may perform operation E10 on the first sub-block Sub-block1 of a selected memory block, among the plurality of memory blocks MEMORY BLOCK<1, 2, . . . >, by using the first erase permission voltage having a default level and the plurality of erase voltages. Next, the control circuit 152 may perform operation E20 on the second sub-block Sub-block2 of the selected memory block by using the second erase permission voltage having a default level and the plurality of erase voltages. Next, the control circuit 152 may perform operation E30 by using the first erase voltage set in operation E10 and the second erase voltage set in operation E20.

When the level of the first erase voltage is higher than the level of the second erase voltage, the control circuit 152 may perform operation E30 of setting the level of the second erase permission voltage to be higher than the level of the first erase permission voltage.

When the level of the second erase voltage is higher than the level of the first erase voltage, the control circuit 152 may perform operation E30 of setting the level of the first erase permission voltage to be higher than the level of the second erase permission voltage.

When the level of the first erase voltage and the level of the second erase voltage are the same, the control circuit 152 may perform operation E30 of setting the level of the first erase permission voltage and the level of the first erase permission voltage to be the same.

When each of the level of the first erase voltage and the level of the second erase voltage is higher than an expected level, the control circuit 152 may perform operation E30 of setting each of the level of the first erase permission voltage and the level of the second erase permission voltage to be higher than a default level.

When each of the level of the first erase voltage and the level of the second erase voltage is higher than an expected level and the level of the first erase voltage is higher than the level of the second erase voltage, the control circuit 152 may perform operation E30 of setting the level of the first erase permission voltage to be higher than a default level and setting the level of the second erase permission voltage to be higher than the level of the first erase permission voltage. For example, the default level is 0 V and the control circuit 152 may set the level of the first erase permission voltage to 0.5 V and the level of the second erase permission voltage to 1 V.

When each of the level of the first erase voltage and the level of the second erase voltage is higher than an expected level and the level of the second erase voltage is higher than the level of the first erase voltage, the control circuit 152 may perform operation E30 of setting the level of the second erase permission voltage to be higher than a default level and setting the level of the first erase permission voltage to be higher than the level of the second erase permission voltage. For example, the default level is 0 V and the control circuit 152 may set the level of the second erase permission voltage to 0.5 V and the level of the first erase permission voltage to 1 V.

When each of the level of the first erase voltage and the level of the second erase voltage is higher than an expected level and the level of the first erase voltage and the level of the second erase voltage are the same, the control circuit 152 may perform operation E30 of setting each of the level of the first erase permission voltage and the level of the second erase permission voltage to be higher than a default level. For example, the default level is 0 V, and the control circuit 152 may set the level of the first erase permission voltage to 0.5 V and the level of the second erase permission voltage to 0.5 V.

When at least one of the levels of the first erase voltage and the second erase voltage is lower than an expected level, the control circuit 152 may perform operation E30 of setting at least one of the levels of the first erase voltage and the second erase permission voltage as a default level.

When at least one of the levels of the first erase voltage and the second erase voltage is lower than an expected level and the level of the first erase voltage is higher than the level of the second erase voltage, the control circuit 152 may perform operation E30 of setting the level of the first erase permission voltage as a default level and setting the level of the second erase permission voltage to be higher than the level of the first erase permission voltage. For example, the default level is 0 V and the control circuit 152 may set the level of the first erase permission voltage to 0 V and the level of the second erase permission voltage to 0.5 V.

When at least one of the levels of the first erase voltage and the second erase voltage is lower than an expected level and the level of the second erase voltage is higher than the level of the first erase voltage, the control circuit 152 may perform operation E30 of setting the level of the second erase permission voltage as a default level and setting the level of the first erase permission voltage to be higher than the level of the second erase permission voltage. For example, the default level is 0 V and the control circuit 152 may set the level of the first erase permission voltage to 0.5 V and the level of the second erase permission voltage to 0 V.

When at least one of the levels of the first erase voltage and the second erase voltage is lower than an expected level and the level of the first erase voltage and the level of the second erase voltage are the same, the control circuit 152 may perform operation E30 of setting each of the levels of the first erase permission voltage and the second erase permission voltage as a default level.

The control circuit 152 may control an operation of the memory device 150 by dividing the operation of the memory device 150 into an operation in a first operation mode and an operation in a second operation mode.

Furthermore, the control circuit 152 may enter the second operation mode after the entry/exit of the first operation mode. In this case, exit timing of the first operation mode and entry timing of the second operation mode may be divided in various manners depending on a method of using the memory device 150. For example, the control circuit 152 may enter the second operation mode in response to the exit of the first operation mode. As another example, the control circuit 152 may enter the second operation mode when at least one power-off and power-on event occurs after the control circuit 152 exits from the first operation mode.

According to an embodiment, the control circuit 152 may enter the first operation mode at timing when a test operation is started, and may exit from the first operation mode at a timing when the test operation is completed.

According to an embodiment, the control circuit 152 may enter the second operation mode at a timing when a normal operation that is entered after a test operation is started.

In this case, the test operation may include a wafer test operation or a package test operation or a built-in self test operation.

According to an embodiment, as illustrated in FIG. 1, the memory device 150 may enter/exit from the first operation mode in order to autonomously perform a built-in self test operation.

According to another embodiment, as illustrated in FIG. 2, an external device 170 for a wafer test or package test operation may be connected to the outside of the memory device 150. In such a case, the control circuit 152 may enter the first operation mode and perform the test operation under the control of the external device 170.

Specifically, the control circuit 152 may sequentially perform operation E10, operation E20, and operation E30 on a selected memory block, among the plurality of memory blocks MEMORY BLOCK<1, 2, . . . >, in the first operation mode. That is, the control circuit 152 may set the level of the first erase voltage by performing operation E10 on the first sub-block Sub-block1 of the selected memory block, may set the level of the second erase voltage by performing operation E20 on the second sub-block Sub-block2 of the selected memory block, and may adjust the level of the first erase permission voltage and the level of the second erase permission voltage by performing operation E30.

In this case, the “selected memory block” that is selected as an execution target for operation E10, operation E20, and operation E30 in the first operation mode may include at least one memory block, among the plurality of memory blocks MEMORY BLOCK<1, 2, . . . >. According to an embodiment, an expected number of memory blocks that belong to the plurality of memory blocks MEMORY BLOCK<1, 2, . . . > and that are disposed in a specific location where the influence of process, voltage, temperature (PVT) will be relatively the greatest may be selected as a “selected memory block”. According to another embodiment, a predetermined number of memory blocks that belong to the plurality of memory blocks MEMORY BLOCK<1, 2, . . . > and that are disposed in a specific location where the influence of PVT will be the greatest and a predetermined number of memory blocks that belong to the plurality of memory blocks MEMORY BLOCK<1, 2, . . . > and that are disposed in a specific location where the influence of PVT will be the smallest may be selected as a “selected memory block”.

After sequentially performing operation E10, operation E20, and operation E30 on the selected memory block in the first operation mode as described above, the control circuit 152 may exit from the first operation mode. That is, the control circuit 152 may adjust the level of the first erase permission voltage and the level of the second erase permission voltage through the entry/exit of the first operation mode.

Furthermore, the control circuit 152 may retain the first erase permission voltage and the second erase permission voltage having the levels adjusted in the first operation mode in a nonvolatile state. For example, the control circuit 152 may store the first erase permission voltage and the second erase permission voltage having the levels adjusted in the first operation mode in some region of the memory cell array 151.

Furthermore, when performing an erase operation on the first sub-block Sub-block1 of each of the plurality of memory blocks MEMORY BLOCK<1, 2, . . . > in the second operation mode, the control circuit 152 may use the first erase permission voltage having the level adjusted in the first operation mode. Likewise, when performing an erase operation on the second sub-block Sub-block2 of each of the plurality of memory blocks MEMORY BLOCK<1, 2, . . . > in the second operation mode, the control circuit 152 may use the second erase permission voltage having the level adjusted in the first operation mode.

After the entry/exit of the first operation mode, the control circuit 152 may enter the second operation mode. In this case, the second operation mode may be a mode that the control circuit 152 enters for a normal operation different from the test operation. Accordingly, as illustrated in FIG. 1, the control circuit 152 may enter the second operation mode only in the construction in which the memory device 150 is included in the memory system 110.

Accordingly, as illustrated in FIG. 1, after entering/exiting from the first operation mode in the construction in which the memory device 150 is included in the memory system 110, the control circuit 152 may enter the second operation mode. In such a case, the control circuit 152 may enter the second operation mode in response to the exit of the first operation mode.

Furthermore, after entering/exiting from the first operation mode in the construction in which the external device 170 for the test operation has been connected to the outside of the memory device 150 as illustrated in FIG. 2, the control circuit 152 may enter the second operation mode in the state in which the construction in which the external device 170 has been connected to the outside of the memory device 150 has been changed into the construction in which the memory device 150 has been included in the memory system 110 as illustrated in FIG. 1. In such a case, the control circuit 152 may enter the second operation mode when at least one power-off and power-on event occurs after exiting from the first operation mode.

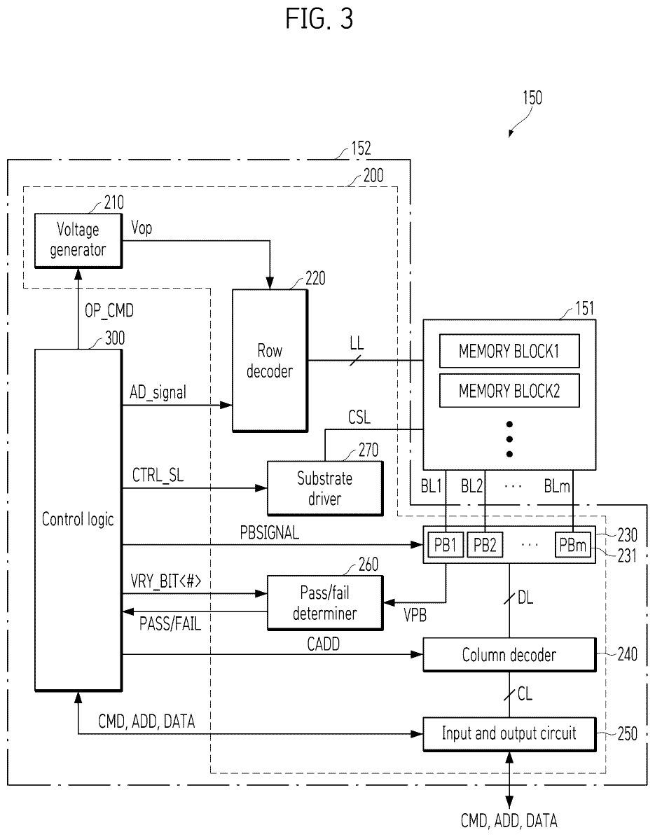

FIG. 3 is a diagram for describing detailed components of the memory device according to an embodiment of the present disclosure.

Referring to FIG. 3, the memory device 150 may include the memory cell array 151 in which data are stored. The memory device 150 may include the control circuit 152 configured to perform a program operation of storing data in the memory cell array 151, a read operation of outputting data stored in the memory cell array 151, and an erase operation of erasing data stored in the memory cell array 151.

The memory cell array 151 may include the plurality of memory blocks MEMORY BLOCK<1, 2, . . . >. For the construction of each of the plurality of memory blocks MEMORY BLOCK<1, 2, . . . >, reference may be made to the constructions of FIGS. 1 and 5.

For reference, it may be seen that FIG. 3 illustrates that a local line LL and a bit line BL are connected to each of the plurality of memory blocks MEMORY BLOCK<1, 2, . . . >. If such a construction is made to correspond to the construction of FIG. 5, it may be seen that the local line LL has a form in which the local line LL includes the plurality of source selection lines SSL<1:2>, the plurality of word lines WL<1:8>, the plurality of dummy word lines DWL<1:2>, and the plurality of drain selection lines DSL<1:2>.

The control circuit 152 may include control logic 300 and a peripheral circuit 200. The peripheral circuit 200 may be configured to perform program, read, and erase operations on each of the plurality of memory blocks MEMORY BLOCK<1, 2, . . . > under the control of the control logic 300.

The peripheral circuit 200 may perform operation E10 on the first sub-block Sub-block1 of a selected memory block, among the plurality of memory blocks MEMORY BLOCK<1, 2, . . . >, or perform operation E20 on the second sub-block Sub-block2 of the selected memory block, under the control of the control logic 300.

The control logic 300 may control the peripheral circuit 200 to perform an operation of checking the level of the first erase voltage by performing operation E10 on the first sub-block Sub-block1 of the selected memory block and an operation of checking the level of the second erase voltage by performing operation E20 on the second sub-block Sub-block2 of the selected memory block in the first operation mode. Furthermore, the control logic 300 may perform operation E30 by using the level of the first erase voltage checked in operation E10 and the level of the second erase voltage checked in operation E20.

More specifically, the peripheral circuit 200 may include a voltage generator 210, a row decoder 220, a page buffer group 230, a column decoder 240, an input and output circuit 250, a pass/fail determiner 260, and a substrate driver 270.

The voltage generator 210 may generate various operation voltages Vop that are used in program, read, and erase operations in response to an operation signal OP_CMD. For example, the voltage generator 210 may generate a program voltage, a read verification voltage, a pass voltage, a first erase permission voltage, a second erase permission voltage, a plurality of erase voltages, an erase verification voltage, and a selection transistor operation voltage under the control of the control logic 300.

The row decoder 220 may transfer the operation voltage Vop to the local line LL that is connected to a selected memory block, among the plurality of memory blocks MEMORY BLOCK<1, 2, . . . >, in response to a row decoder control signal AD_signal. For example, the row decoder 220 may supply the plurality of word lines WL<1:8> included in the local line LL with the first erase permission voltage, the second erase permission voltage, and the erase verification voltage generated by the voltage generator 210 and an erase prevention voltage, in response to the row decoder control signal AD_signal.

The page buffer group 230 may include multiple page buffers PB1 to PBn that are connected to bit lines BL1 to BLn. The multiple page buffers PB1 to PBn may operate in response to a page buffer control signal PBSIGNAL. For example, the multiple page buffers PB1 to PBn may control the bit lines BL1 to BLn in a floating state when performing an operation of applying a plurality of erase voltages during an erase operation, and may sense the current or voltage level of each of the bit lines BL1 to BLn after the start of an erase verification operation.

The column decoder 240 may transmit data between the input and output circuit 250 and the page buffer group 230 in response to a column address CADD. For example, the column decoder 240 may exchange data with the page buffer 231 through a data line DL, or may exchange data with the input and output circuit 250 through a column line CL.

The input and output circuit 250 may transfer a command CMD and an address ADD received from the controller (130 in FIG. 1) to the control logic 300 or may exchange data DATA with the column decoder 240.

After the start of a read operation, a read verification operation, or an erase verification operation, the pass/fail determiner 260 may generate a reference current in response to a permission bit VRY_BIT<#>, and may output a pass signal PASS or a fail signal FAIL by comparing a sensing voltage VPB received from the page buffer group 230 and a reference voltage generated based on the reference current.

The substrate driver 270 may be connected to a memory cell included in the memory cell array 151 through the common source line CSL, and may control a voltage that is applied to the common source line CSL. The substrate driver 270 may supply the substrate with any of a plurality of erase voltages through the common source line CSL after the start of an erase operation.

The substrate driver 270 may receive a source line control signal CTRL_SL from the control logic 300, and may control a source line voltage that is applied to the common source line CSL based on the source line control signal CTRL_SL.

The control logic 300 may control the peripheral circuit 200 by outputting the operation signal OP_CMD, the row decoder control signal AD_signal, the page buffer control signal PBSIGNAL, and the permission bit VRY_BIT<#>, in response to the command CMD and the address ADD. Furthermore, the control logic 300 may determine whether a read verification operation or an erase verification operation is a pass or fail in response to the pass or fail signal PASS or FAIL.

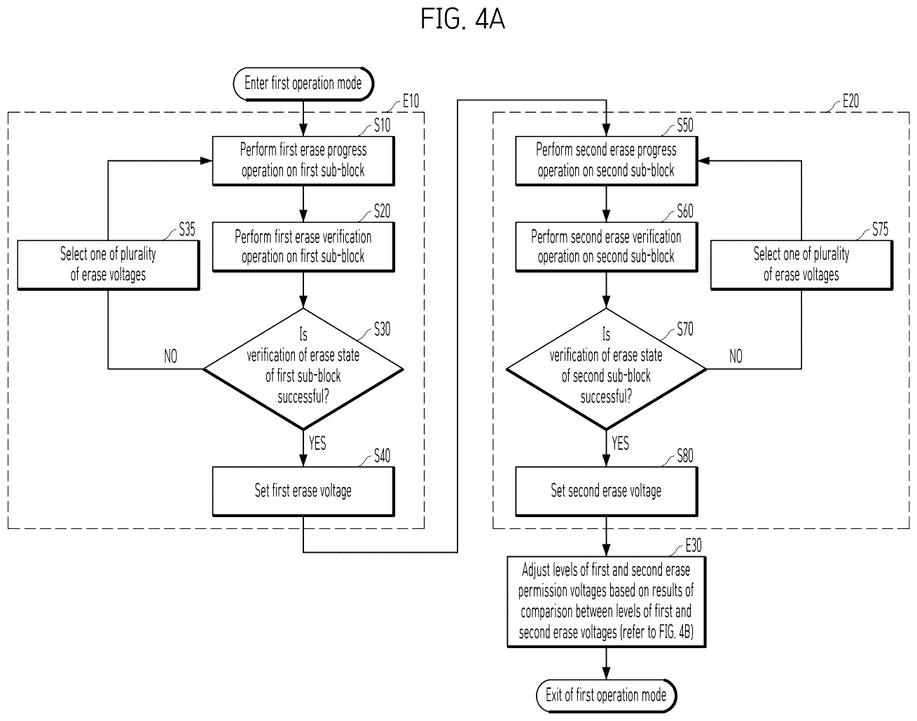

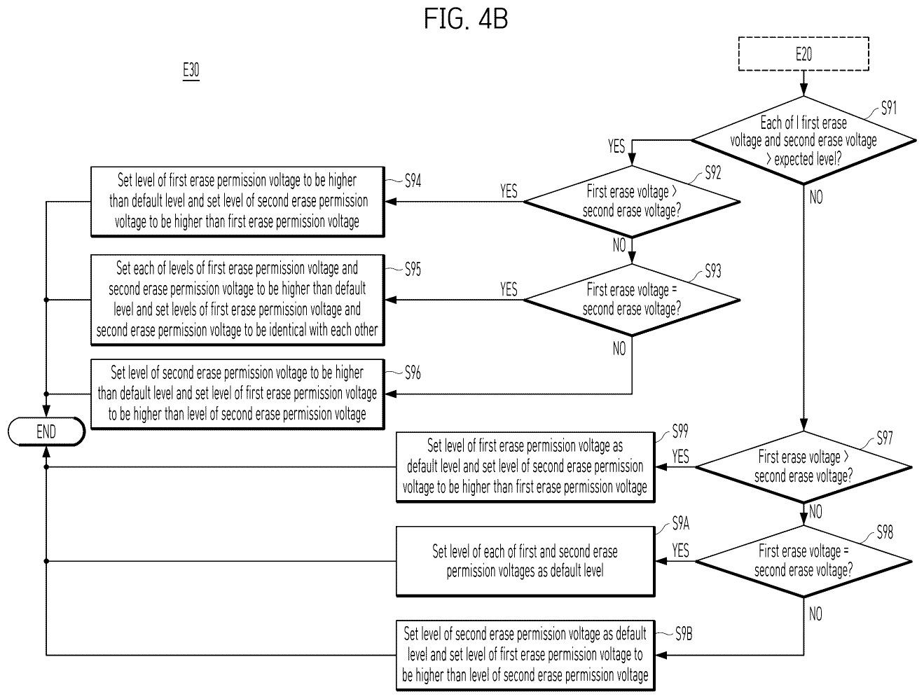

FIGS. 4A and 4B are flowcharts for describing an erase operation that is performed in the memory device according to an embodiment of the present disclosure.

Referring to FIGS. 4A and 4B, it may be seen that after entering the first operation mode, the memory device 150 according to an embodiment of the present disclosure sets the level of the first erase voltage by performing operation E10 on the first sub-block Sub-block1 of a selected memory block, among the plurality of memory blocks MEMORY BLOCK<1, 2, . . . >, sets the level of the second erase voltage by performing operation E20 on the second sub-block Sub-block2 of the selected memory block, and then adjusts the levels of the first erase permission voltage and the second erase permission voltage by performing operation E30. For reference, in FIGS. 4A and 4B, operation E10, operation E20, and operation E30 are sequentially performed in the first operation mode, but this is merely illustrative. Operation E20, operation E10, and operation E30 may be sequentially performed depending on a designer's choice.

Referring to FIG. 4A, operation E10 may be performed according to the following sequence.

First, a first erase progress operation may be performed by applying a first erase permission voltage and any of a plurality of erase voltages to the first sub-block Sub-block1 of a selected memory block, among the plurality of memory blocks MEMORY BLOCK<1, 2, . . . > (S10).

After S10, in order to check whether each of the threshold voltage levels of memory cells included in the first sub-block Sub-block1 of the selected memory block in the first erase progress operation is lower than the level of an erase verification voltage, a first erase verification operation of applying the erase verification voltage to the first sub-block Sub-block1 of the selected memory block may be performed (S20).

Whether the verification of the erase state of the first sub-block Sub-block1 of the selected memory block is successful may be checked (S30) through the first erase verification operation performed in S20.

When the verification of the erase state of the first sub-block Sub-block1 of the selected memory block fails (NO in S30), any of the plurality of erase voltages may be selected again (S35). Furthermore, S10, S20, S30, and S35 may be repeated by using the erase voltage selected in S35 until the verification of the erase state of the first sub-block Sub-block1 of the selected memory block is successful (YES in S30). In this case, the plurality of erase voltages that are selected in S35 may be erase voltages that are sequentially increased in proportion to the number of times that S35 is repeated according to the ISPE method. For example, the plurality of erase voltages may be sequentially selected in S35 by using a method of using an erase voltage having the lowest level, among the plurality of erase voltages in S10 that is performed for the first time and using an erase voltage having the second lowest level, among the plurality of erase voltages, in S10 that is performed for the second time.

When the verification of the erase state of the first sub-block Sub-block1 of the selected memory block is successful (YES in S30), the erase voltage that was selected in S35 performed before and that was used in S10, that is, any of the plurality of erase voltages, may be set as a first erase voltage (S40).

Referring to FIG. 4A, operation E20 may be performed according to the following sequence.

First, a second erase progress operation may be performed by applying a second erase permission voltage and any of the plurality of erase voltages to the second sub-block Sub-block2 of a selected memory block, among the plurality of memory blocks MEMORY BLOCK<1, 2, . . . > (S50). In this case, the selected memory block, that is, a target for operation E10, and the selected memory block, that is, a target for operation E20, may be the same memory block.

After S50, in order to check whether each of the threshold voltage levels of memory cells included in the second sub-block Sub-block2 of the selected memory block is lower than the level of an erase verification voltage in the second erase progress operation, a second erase verification operation of applying the erase verification voltage to the second sub-block Sub-block2 of the selected memory block may be performed (S60).

Whether the verification of the erase state of the second sub-block Sub-block2 of the selected memory block is successful may be checked (S70) through the second erase verification operation performed in S60.

When the verification of the erase state of the second sub-block Sub-block2 of the selected memory block fails (NO in S70), any of the plurality of erase voltages may be selected again (S75). Furthermore, S50, S60, S70, and S75 may be repeated by using the erase voltage selected in S75 until the verification of the erase state of the second sub-block Sub-block2 of the selected memory block is successful (YES in S70). In this case, the plurality of erase voltages that are selected in S75 may be erase voltages that are sequentially increased in proportion to the number of times that S75 is repeated according to the ISPE method. For example, the plurality of erase voltages may be sequentially selected in S75 by using a method of using an erase voltage having the lowest level, among the plurality of erase voltages in S50 that is performed for the first time and using an erase voltage having the second lowest level, among the plurality of erase voltages, in S50 that is performed for the second time.

When the verification of the erase state of the second sub-block Sub-block2 of the selected memory block is successful (YES in S70), the erase voltage that was selected in S75 performed before and that was used in S50, that is, any of the plurality of erase voltages, may be set as a second erase voltage (S80).

Referring to FIG. 4B, operation E30 may be performed according to the following sequence.

First, whether each of the level of the first erase voltage set in operation E10 that was performed before and the level of the second erase voltage set in operation E20 that was performed before is greater than an expected level may be checked (S91).

When each of the level of the first erase voltage and the level of the second erase voltage is greater than the expected level in S91 (YES in S91), whether the level of the first erase voltage is higher than the level of the first erase voltage may be checked (S92).

When the level of the first erase voltage is higher than the level of the second erase voltage in S92 (YES in S92), the level of the first erase permission voltage may be set to be higher than a default level, and the level of the second erase permission voltage may be set to be higher than the first erase permission voltage (S94).

When the level of the first erase voltage is equal to or lower than the level of the second erase voltage in S92 (NO in S92), whether the level of the first erase voltage and the level of the second erase voltage are the same may be checked (S93).

When the level of the first erase voltage and the level of the second erase voltage are the same in S93 (YES in S93), each of the level of the first erase permission voltage and the level of the second erase permission voltage may be set to be higher than the default level (S95).

When the level of the first erase voltage and the level of the second erase voltage are not the same level in S93 (NO in S93), the second erase permission voltage may be set to be higher than the default level, and the level of the first erase permission voltage may be set to be higher than the level of the second erase permission voltage (S96).

When at least one of the levels of the first erase voltage and the second erase voltage is equal to or lower than the expected level in S91 (NO in S91), whether the level of the first erase voltage is higher than the level of the first erase voltage may be checked (S97).

When the level of the first erase voltage is higher than the level of the second erase voltage in S97 (YES in S97), the level of the first erase permission voltage may be set as the default level, and the level of the second erase permission voltage may be set to be higher than the level of the first erase permission voltage (S99).

When the level of the first erase voltage is equal to or lower than the level of the second erase voltage in S97 (NO in S97), whether the level of the first erase voltage and the level of the second erase voltage are the same level may be checked (S98).

When the level of the first erase voltage and the level of the second erase voltage are the same level in S98 (YES in S98), each of the levels of the first erase permission voltage and the second erase permission voltage may be set as the default level (S9A).

When the level of the first erase voltage and the level of the second erase voltage are not the same level in S98 (NO in S98), the level of the second erase permission voltage may be set as the default level, and the level of the first erase permission voltage may be set to be higher than the level of the second erase permission voltage (S9B).

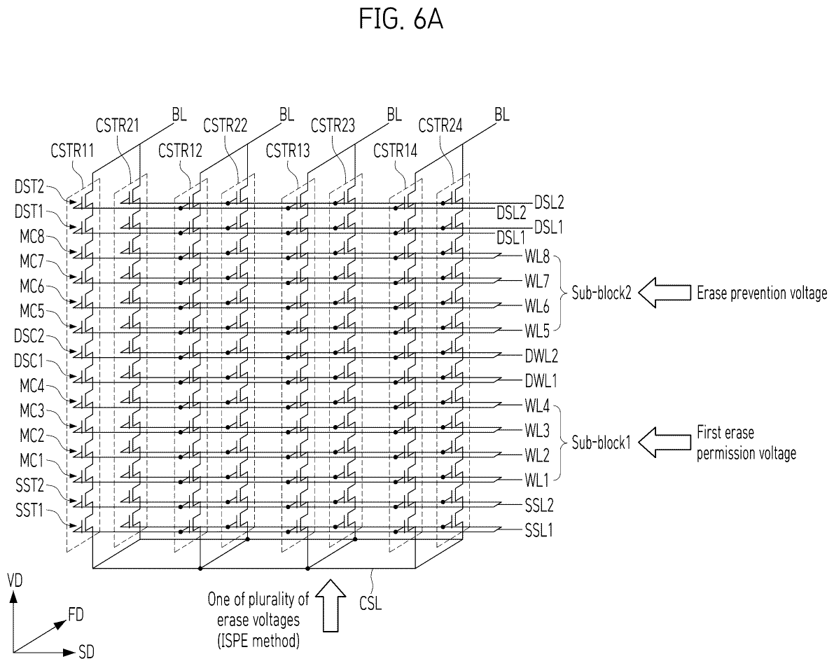

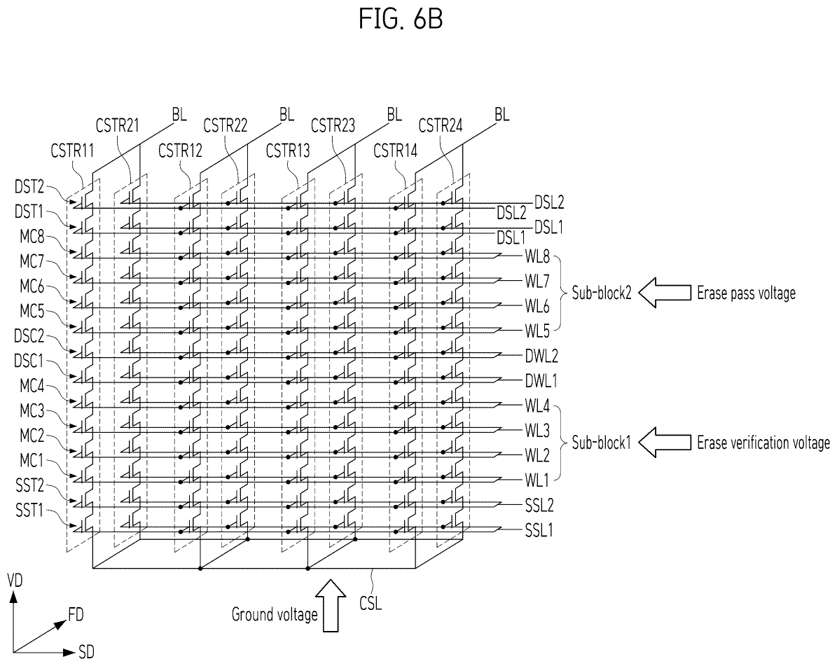

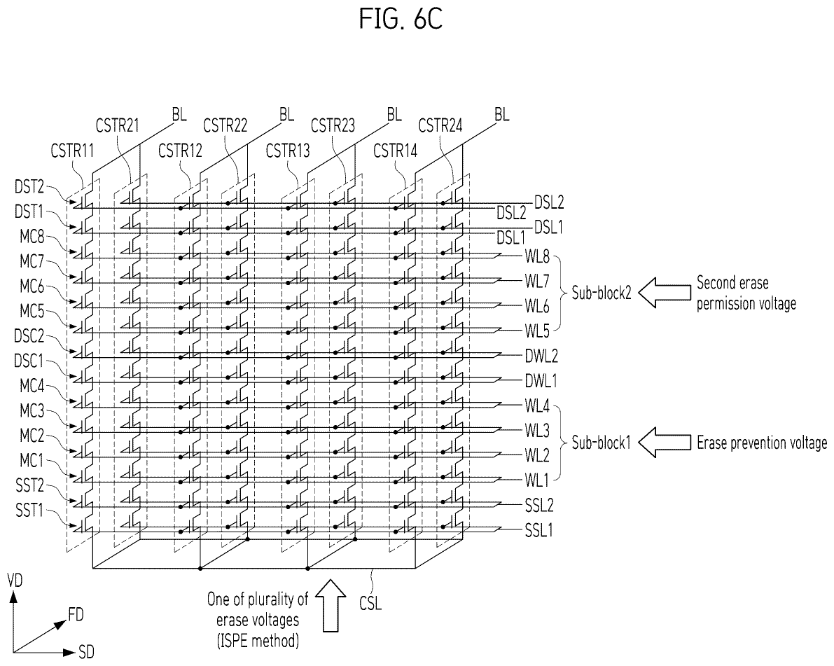

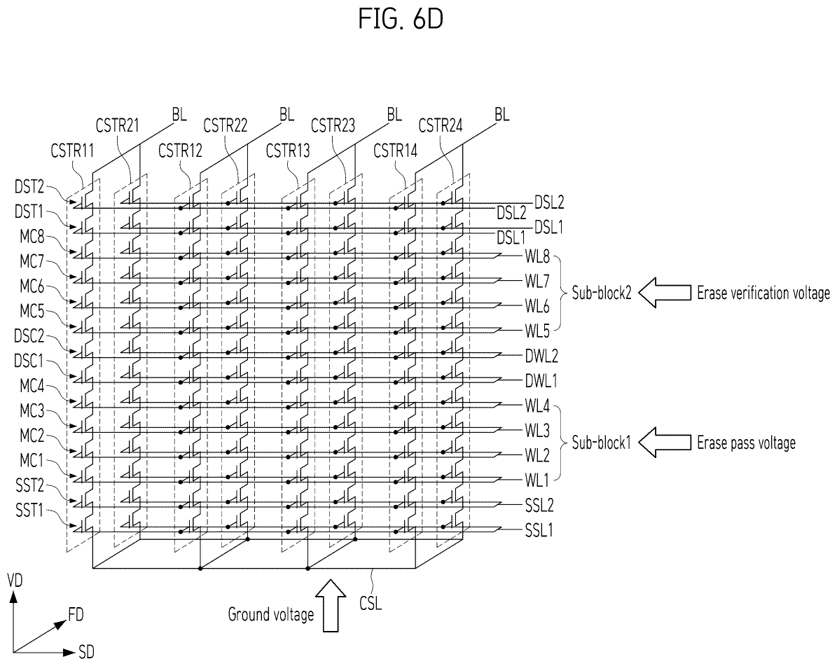

FIGS. 6A to 6D are diagrams for describing an erase operation that is performed in a sub-block unit in the memory device according to an embodiment of the present disclosure.

First, FIGS. 6A and 6B illustrate voltages applied to an erase target memory block when an erase operation is performed on the first sub-block Sub-block1 included in each of the plurality of memory blocks MEMORY BLOCK<1, 2, . . . >.

Furthermore, FIGS. 6C and 6D illustrate voltages applied to an erase target memory block when an erase operation is performed on the second sub-block Sub-block2 included in each of the plurality of memory blocks MEMORY BLOCK<1, 2, . . . >.

Specifically, it may be seen from FIG. 6A which voltage is applied to an erase target memory block in order to perform a first erase progress operation on the first sub-block Sub-block1 of the erase target memory block.

First, a first erase permission voltage may be applied to the first to fourth word lines WL<1:4> corresponding to the first sub-block Sub-block1 of the erase target memory block. That is, in order to lower the threshold voltage levels of memory cells included in the first sub-block Sub-block1 of the erase target memory block, the first erase permission voltage may be applied to the first to fourth word lines WL<1:4>. For example, the level of the first erase permission voltage may be set as a voltage level between 0 V and 2 V.

Furthermore, an erase prevention voltage may be applied to the word lines WL<5:8> corresponding to the second sub-block Sub-block2 of the erase target memory block. That is, in order to maintain the threshold voltage levels of memory cells included in the second sub-block Sub-block2 of the erase target memory block without any change, the erase prevention voltage may be applied to the fifth to eighth word lines WL<5:8> corresponding to the second sub-block Sub-block2 of the erase target memory block. For example, the erase prevention voltage may be set as a voltage level between 18 V and 20 V.

Furthermore, one of a plurality of erase voltages may be applied to the common source line CSL connected to the substrate. In this case, as in the above description, one of the plurality of erase voltages may be selected according to a set sequence whenever the first erase progress operation is repeated according to the ISPP method, and may be applied to the common source line CSL. That is, for example, an erase voltage of 18 V may be selected in the 1^{st} first erase progress operation that is started for the first time, an erase voltage of 18.5 V may be selected in the 2^{nd} first erase progress operation, and an erase voltage of 19 V may be selected in the 3^{rd} first erase progress operation.

Furthermore, it may be seen from FIG. 6B which voltage is applied to an erase target memory block in order to perform a first erase verification operation on the first sub-block Sub-block1 of the erase target memory block.

First, an erase verification voltage may be applied to the first to fourth word lines WL<1:4> corresponding to the first sub-block Sub-block1 of the erase target memory block. That is, in order to check whether each of the threshold voltage levels of memory cells included in the first sub-block Sub-block1 of the erase target memory block is lower than the level of the erase verification voltage, the erase verification voltage may be applied to the first to fourth word lines WL<1:4> corresponding to the first sub-block Sub-block1 of the erase target memory block. For example, the level of the erase verification voltage may be set as a voltage level between 4.5 V and 5 V.

Furthermore, an erase pass voltage may be applied to the word lines WL<5:8> corresponding to the second sub-block Sub-block2 of the erase target memory block. That is, in order to exclude memory cells included in the second sub-block Sub-block2 of the erase target memory block from a target on which the first erase verification operation is performed (i.e., in order to protect unerased memory cells), the erase pass voltage may be applied to the fifth to eighth word lines WL<5:8> corresponding to the second sub-block Sub-block2 of the erase target memory block. For example, the erase pass voltage may be set as a voltage level between 10 V and 12 V.

Furthermore, a ground voltage VSS may be applied to the common source line CSL connected to the substrate.

Furthermore, it may be seen from FIG. 6C which voltage is applied to an erase target memory block in order to perform a second erase progress operation on the second sub-block Sub-block2 of the erase target memory block.

First, a second erase permission voltage may be applied to the word lines WL<5:8> corresponding to the second sub-block Sub-block2 of the erase target memory block. That is, in order to lower the threshold voltage levels of memory cells included in the second sub-block Sub-block2 of the erase target memory block, the second erase permission voltage may be applied to the fifth to eighth word lines WL<5:8> corresponding to the second sub-block Sub-block2 of the erase target memory block. For example, the level of the second erase permission voltage may be set as a voltage level between 0 V and 2 V. Furthermore, an erase prevention voltage may be applied to the first to fourth word lines WL<1:4> corresponding to the first sub-block Sub-block1 of the erase target memory block. That is, in order to maintain the threshold voltage levels of memory cells included in the first sub-block Sub-block1 of the erase target memory block without any change, the erase prevention voltage may be applied to the first to fourth word lines WL<1:4> corresponding to the first sub-block Sub-block1 of the erase target memory block. For example, the erase prevention voltage may be set as a voltage level between 18 V and 20 V.

Furthermore, one of a plurality of erase voltages may be applied to the common source line CSL connected to the substrate. In this case, as in the above description, one of the plurality of erase voltages may be selected according to a set sequence whenever the second erase progress operation is repeated according to the ISPP method, and may be applied to the common source line CSL. That is, for example, an erase voltage of 18 V may be selected in the 1^{st} second erase progress operation that is started for the first time, an erase voltage of 18.5 V may be selected in the 2^{nd} second erase progress operation, and an erase voltage of 19 V may be selected in the 3^{rd} second erase progress operation.

Furthermore, it may be seen from FIG. 6D which voltage is applied to an erase target memory block in order to perform a first erase verification operation on the second sub-block Sub-block2 of the erase target memory block.

First, an erase verification voltage may be applied to the word lines WL<5:8> corresponding to the second sub-block Sub-block2 of the erase target memory block. That is, in order to check whether each of the threshold voltage levels of memory cells included in the second sub-block Sub-block2 of the erase target memory block is lower than the level of the erase verification voltage, the erase verification voltage may be applied to the fifth to eighth word lines WL<5:8> corresponding to the second sub-block Sub-block2 of the erase target memory block. For example, the level of the erase verification voltage may be set as a voltage level between 4.5 V and 5 V.

Furthermore, an erase pass voltage may be applied to the first to fourth word lines WL<1:4> corresponding to the first sub-block Sub-block1 of the erase target memory block. That is, in order to exclude memory cells included in the first sub-block Sub-block1 of the erase target memory block from a target on which the second erase verification operation is performed (i.e., in order to protect unerased memory cells), the erase pass voltage may be applied to the first to fourth word lines WL<1:4> corresponding to the first sub-block Sub-block1 of the erase target memory block. For example, the level of the erase pass voltage may be set as a voltage level between 10 V and 12 V.

Furthermore, the ground voltage VSS may be applied to the common source line CSL connected to the substrate.

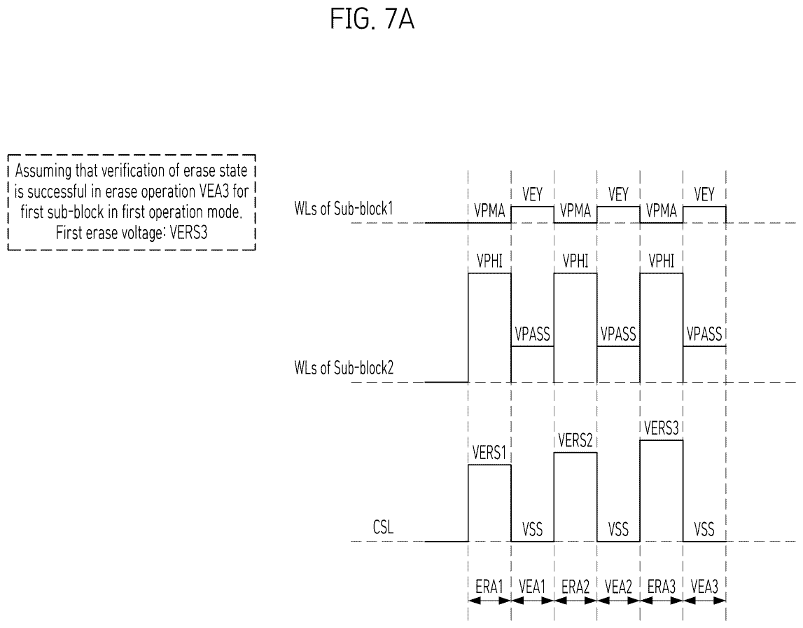

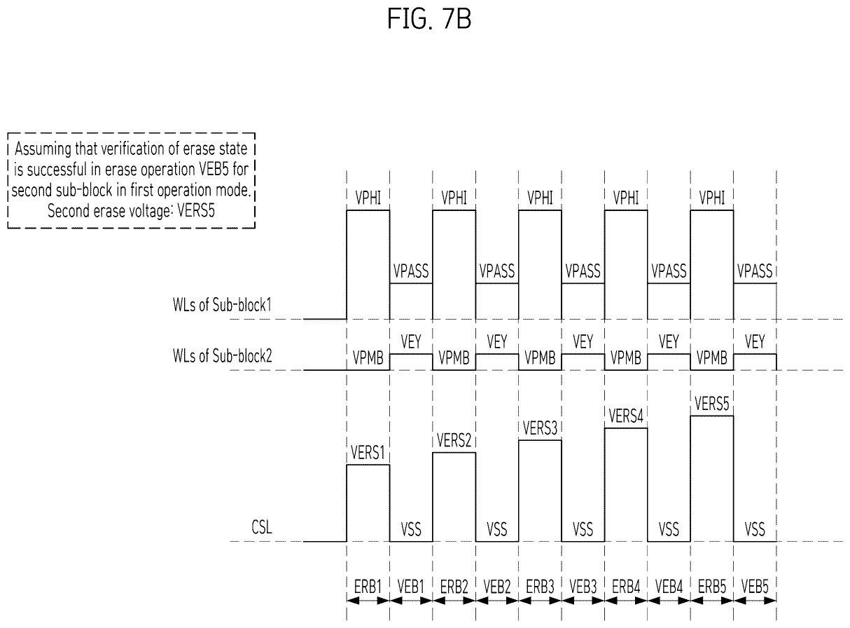

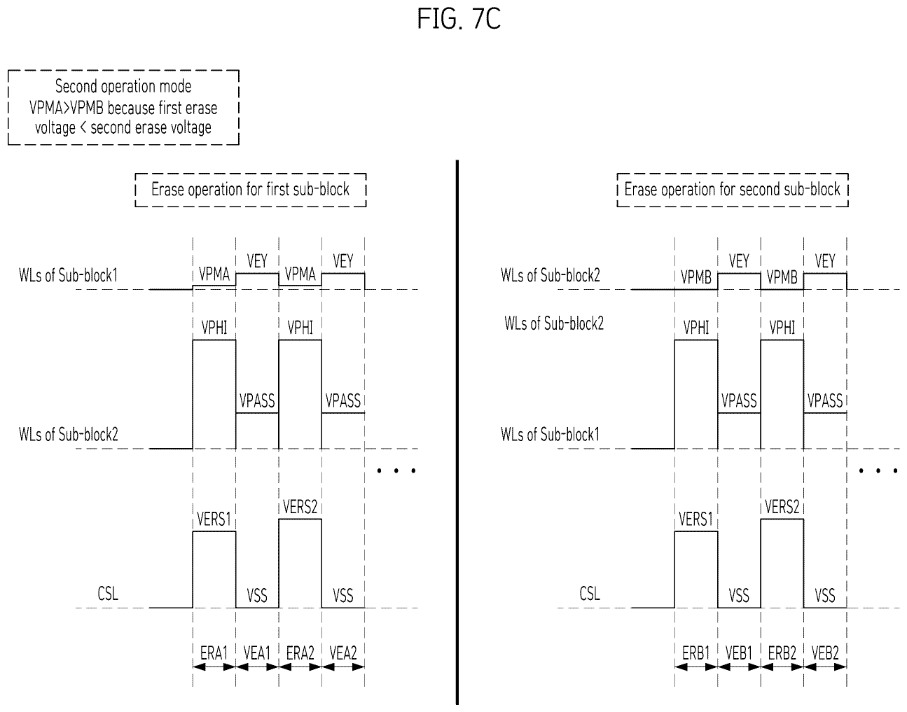

FIGS. 7A to 7C are timing diagrams for describing an erase operation that is performed in the memory device according to an embodiment of the present disclosure.

First, FIG. 7A may illustrate an erase operation that is performed on the first sub-block Sub-block1 of a selected memory block in the first operation mode, that is, operation E10.

Specifically, a first erase progress operation ERAx of applying a first erase permission voltage VPMA to word lines (WLs of Sub-block1) corresponding to the first sub-block Sub-block1 of the selected memory block, among the plurality of memory blocks MEMORY BLOCK<1, 2, . . . >, applying an erase prevention voltage VPHI to word lines (WLs of Sub-block2) corresponding to the second sub-block Sub-block2 of the selected memory block, and applying any of a plurality of erase voltages VERSx to the common source line CSL connected to the substrate may be performed.

Furthermore, a first erase verification operation VEAx of applying an erase verification voltage VEY to word lines (WLs of Sub-block1) corresponding to the first sub-block Sub-block1 of the selected memory block, among the plurality of memory blocks MEMORY BLOCK<1, 2, . . . >, applying a erase pass voltage VPASS to word lines (WLs of Sub-block2) corresponding to the second sub-block Sub-block2 of the selected memory block, and applying a ground voltage VSS to the common source line CSL may be performed. In this case, x may be a natural number equal to or greater than 1.

More specifically, after an erase operation for the first sub-block Sub-block1 is started, in the 1^{st} first erase progress operation ERA1, the first erase permission voltage VPMA may be applied to the word lines (WLs of Sub-block1) corresponding to the first sub-block Sub-block1, the erase prevention voltage VPHI may be applied to the word lines (WLs of Sub-block2) corresponding to the second sub-block Sub-block2, and “VERS1”, among the plurality of erase voltages VERSx, may be applied to the common source line CSL.

Next, in the 1^{st} first erase verification operation VEA1, the erase verification voltage VEY may be applied to the word lines (WLs of Sub-block1) corresponding to the first sub-block Sub-block1, the erase pass voltage VPASS may be applied to the word lines (WLs of Sub-block2) corresponding to the second sub-block Sub-block2, and the ground voltage VSS may be applied to the common source line CSL.

When the verification of the erase state of the first sub-block Sub-block1 is successful in the 1^{st} first erase verification operation VEA1, the 2^{nd} first erase progress operation ERA2 might not be performed. However, in FIG. 7A, the verification of the erase state of the first sub-block Sub-block1 fails in the 1^{st} first erase verification operation VEA1. Accordingly, it may be seen that the 2^{nd} first erase progress operation ERA2 using “VERS2”, among the plurality of erase voltages VERSx, is performed and the 2^{nd} first erase verification operation VEA2 is then performed.

Likewise, when the verification of the erase state of the first sub-block Sub-block1 is successful in the 2^{nd} first erase verification operation VEA2, the 3^{rd} first erase progress operation ERA3 might not be performed. However, in FIG. 7A, the verification of the erase state of the first sub-block Sub-block1 fails in the 2^{nd} first erase verification operation VEA2. Accordingly, it may be seen that the 3^{rd} first erase progress operation ERA3 using “VERS3”, among the plurality of erase voltages VERSx, is performed and the 3^{rd} first erase verification operation VEA3 is performed.

Furthermore, in FIG. 7A, the verification of the erase state of the first sub-block Sub-block1 is successful in the 3^{rd} first erase verification operation VEA3. Accordingly, “VERS3” that was used in the 3^{rd} first erase progress operation ERA3 performed right before the 3^{rd} first erase verification operation VEA3 was performed may be set as a first erase voltage.

Furthermore, FIG. 7B may illustrate an erase operation that is performed on the first sub-block Sub-block1 of a selected memory block in the first operation mode, that is, operation E20.

Specifically, a second erase progress operation ERBx of applying the erase prevention voltage VPHI to the word lines (WLs of Sub-block1) corresponding to the first sub-block Sub-block1 of a selected memory block, among the plurality of memory blocks MEMORY BLOCK<1, 2, . . . >, applying a second erase permission voltage VPMB to the word lines (WLs of Sub-block2) corresponding to the second sub-block Sub-block2 of the selected memory block, and applying any of the plurality of erase voltages VERSx to the common source line CSL connected to the substrate may be performed.

Furthermore, a second erase verification operation VEBx of applying an erase pass voltage VPASS to the word lines (WLs of Sub-block1) corresponding to the first sub-block Sub-block1 of the selected memory block, among the plurality of memory blocks MEMORY BLOCK<1, 2, . . . >, applying the erase verification voltage VEY to the word lines (WLs of Sub-block2) corresponding to the second sub-block Sub-block2 of the selected memory block, and applying the ground voltage VSS to the common source line CSL may be performed. In this case, x may be a natural number equal to or greater than 1.

More specifically, after an erase operation for the second sub-block Sub-block2 is started, in the 1^{st} second erase progress operation ERB1, the second erase permission voltage VPMB may be applied to the word lines (WLs of Sub-block2) corresponding to the second sub-block Sub-block2 of the selected memory block, the erase prevention voltage VPHI may be applied to the word lines (WLs of Sub-block1) corresponding to the first sub-block Sub-block1, and an erase voltage “VERS1”, among the plurality of erase voltages VERSx, may be applied to the common source line CSL.

Next, in the 1^{st} second erase verification operation VEB1, the erase verification voltage VEY may be applied to the word lines (WLs of Sub-block2) corresponding to the second sub-block Sub-block2 of the selected memory block, the erase pass voltage VPASS may be applied to the word lines (WLs of Sub-block1) corresponding to the first sub-block Sub-block1, and the ground voltage VSS may be applied to the common source line CSL.

When the verification of the erase state is successful in the 1^{st} second erase verification operation VEB1, the 2^{nd} second erase progress operation ERB2 might not be performed. However, in FIG. 7B, the verification of the erase state of the second sub-block Sub-block2 fails in the 1^{st} second erase verification operation VEB1. Accordingly, it may be seen that the 2^{nd} second erase progress operation ERB2 using an erase voltage “VERS2”, among the plurality of erase voltages VERSx, is performed and the 2^{nd} second erase verification operation VEB2 is then performed.

Likewise, when the verification of the erase state of the second sub-block Sub-block2 is successful in the 2^{nd} second erase verification operation VEB2, the 3^{rd} second erase progress operation ERB3 might not be performed. However, in FIG. 7B, the verification of the erase state of the second sub-block Sub-block2 fails in the 2^{nd} second erase verification operation VEB2. Accordingly, it may be seen that the 3^{rd} second erase progress operation ERB3 using an erase voltage “VERS3”, among the plurality of erase voltages VERSx, is performed and the 3^{rd} second erase verification operation VEB3 is then performed.

It may be seen that in such a manner, in FIG. 7B, the 5th second erase progress operation ERB5 using an erase voltage “VERS5”, among the plurality of erase voltages VERSx, is performed and the 5th second erase verification operation VEB5 is then performed.

Furthermore, in FIG. 7B, a case in which the verification of the erase state of the second sub-block Sub-block2 is successful in the 5th second erase verification operation VEB5 is illustrated. Accordingly, an erase voltage “VERS5” that was used in the 5th second erase progress operation ERB5 performed right before the 5th second erase verification operation VEB5 was performed may be set as a second erase voltage.

It may be seen that the first erase voltage determined in operation E10 in the first operation mode, which has been illustrated in FIG. 7A, is the erase voltage “VERS3” having the third higher level, among the plurality of erase voltages VERSx, and the second erase voltage determined in operation E20 in the first operation mode, which has been illustrated in FIG. 7B, has a lower level than the erase voltage “VERS5” having the fifth higher level, among the plurality of erase voltages VERSx.

Accordingly, although not materialized in the drawings, in operation E30 in the first operation mode, the level of the first erase permission voltage VPMA may be set to be higher than the level of the second erase permission voltage VEYB.

Furthermore, FIG. 7C illustrates an erase operation for each of the plurality of memory blocks MEMORY BLOCK<1, 2, . . . >, which is performed in the second operation mode, after the level of the first erase permission voltage VPMA is set to be higher than the level of the second erase permission voltage VEYB in the first operation mode.

Specifically, an erase operation for the first sub-block Sub-block1 of an erase target block, among the plurality of memory blocks MEMORY BLOCK<1, 2, . . . >, in the second operation mode may be performed by repeating a first erase progress operation ERAx and a first erase verification operation VEAx.

More specifically, the first erase progress operation ERAx of applying the first erase permission voltage VPMA having a relatively higher level than the second erase permission voltage VEYB to the word line (WLs of Sub-block1) corresponding to the first sub-block Sub-block1 of the erase target block, applying the erase prevention voltage VPHI to the word lines (WLs of Sub-block2) corresponding to the second sub-block Sub-block2, and applying any of the plurality of erase voltages VERSx to the common source line CSL connected to the substrate may be performed.

Next, the first erase verification operation VEAx of applying the erase verification voltage VEY to the word line (WLs of Sub-block1) corresponding to the first sub-block Sub-block1 of the erase target block, applying the erase pass voltage VPASS to the word lines (WLs of Sub-block2) corresponding to the second sub-block Sub-block2, and applying the ground voltage VSS to the common source line CSL connected to the substrate may be performed. In this case, x may be a natural number equal to or greater than 1.

Furthermore, an erase operation for the second sub-block Sub-block2 of an erase target block, among the plurality of memory blocks MEMORY BLOCK<1, 2, . . . >, in the second operation mode may be performed by repeating a second erase progress operation ERBx and a second erase verification operation VEBx.

More specifically, the second erase progress operation ERBx of applying the second erase permission voltage VPMB having a relatively lower level than the first erase permission voltage VEYA to the word lines (WLs of Sub-block2) corresponding to the second sub-block Sub-block2 of the erase target block, applying the erase prevention voltage VPHI to the word lines (WLs of Sub-block1) corresponding to the first sub-block Sub-block1, and applying any of the plurality of erase voltages VERSx to the common source line CSL connected to the substrate may be performed.

Next, the second erase verification operation VEBx of applying the erase verification voltage VEY to the word lines (WLs of Sub-block2) corresponding to the second sub-block Sub-block2 of the erase target block, applying the erase pass voltage VPASS to the word lines (WLs of Sub-block1) corresponding to the first sub-block Sub-block1, and applying the ground voltage VSS to the common source line CSL connected to the substrate may be performed. In this case, x may be a natural number equal to or greater than 1.

For reference, FIGS. 7A to 7C illustrate a case in which the level of the first erase permission voltage VPMA is set to be higher than the level of the second erase permission voltage VEYB in operation E30 because the level of the first erase voltage, which has been set in operation E10, is checked to be lower than the level of the second erase voltage, which has been set in operation E20, in the first operation mode. Although not materialized in the timing diagrams of FIGS. 7A to 7C, the level of the first erase permission voltage VPMA and the level of the second erase permission voltage VEYB may be set in various forms in operation E30 as described with reference to FIG. 4B, and the results thereof may be applied to an erase operation that is performed in the second operation mode.

Although various embodiments of the present disclosure have been described for illustrative purposes, it will be apparent to those skilled in the art that various changes and modifications may be made without departing from the spirit and scope of the invention as defined in the following claims. Furthermore, the embodiments may be combined to form additional embodiments.

What is claimed is:

1. A memory device comprising:
a plurality of memory blocks each including first and second sub-blocks; and
a control circuit configured to:
apply a first erase permission voltage and a first erase voltage among a plurality of erase voltages to a first sub-block of a selected memory block among the plurality of memory blocks, and check a level of the first erase voltage applied when a verification of an erase state of the first sub-block is successful,
apply a second erase permission voltage and a second erase voltage among the plurality of erase voltages to a second sub-block of the selected memory block, and check a level of the second erase voltage applied when a verification of an erase state of the second sub-block is successful, and
adjust levels of the first and second erase permission voltages based on a result of a comparison between the levels of the first and second erase voltages.

2. The memory device of claim 1, wherein the control circuit is configured to:
in a first operation mode, sequentially perform, on the selected memory block, an operation of checking the level of the first erase voltage, an operation of checking the level of the second erase voltage, and an operation of adjusting the levels of the first and second erase permission voltages; and
in a second operation mode subsequent to the first operation mode, use the first erase permission voltage having the level adjusted in the first operation mode when performing an erase operation on the first sub-block of each of the plurality of memory blocks, and use the second erase permission voltage having the level adjusted in the first operation mode when performing an erase operation on the second sub-block of each of the plurality of memory blocks.

3. The memory device of claim 2, wherein:
each of the plurality of memory blocks comprises a plurality of word lines vertically stacked over a substrate;
a first word line stacked at a first side of a reference word line, among the plurality of word lines, is set as the first sub-block; and
a second word line stacked at a second side of the reference word line is set as the second sub-block.

4. The memory device of claim 3, wherein the control circuit is configured to:
alternately perform a first erase progress operation of applying one erase voltage among the plurality of erase voltages according to a set sequence, to the substrate corresponding to the selected memory block and a first erase verification operation of applying an erase verification voltage to the first word line of the selected memory block, in a state in which the first erase permission voltage having a default level is applied to the first word line of the selected memory block; and
set, as the first erase voltage, an erase voltage applied to the substrate corresponding to the selected memory block in the first erase progress operation performed before the verification of the erase state of the first sub-block is successful in the first erase verification operation.

5. The memory device of claim 4, wherein the control circuit is configured to:
alternately perform a second erase progress operation of applying one erase voltage among the plurality of erase voltages according to a set sequence, to the substrate corresponding to the selected memory block and a second erase verification operation of applying an erase verification voltage to the second word line of the selected memory block, in a state in which the second erase permission voltage having the default level is applied to the second word line of the selected memory block; and
set, as the second erase voltage, an erase voltage applied to the substrate corresponding to the selected memory block in the second erase progress operation performed before the verification of the erase state of the second sub-block is successful in the second erase verification operation.

6. The memory device of claim 5, wherein the control circuit is configured to:
set the level of the second erase permission voltage to be higher than the level of the first erase permission voltage when the level of the first erase voltage is higher than the level of the second erase voltage;
set the level of the first erase permission voltage to be higher than the level of the second erase permission voltage when the level of the second erase voltage is higher than the level of the first erase voltage; and
set the level of the first erase permission voltage and the level of the first erase permission voltage to be identical with each other when the level of the first erase voltage and the level of the second erase voltage are identical with each other.

7. The memory device of claim 6, wherein the control circuit is configured to:
set the level of each of the first and second erase permission voltages to be higher than the default level when each of the levels of the first and second erase voltages is higher than an expected level; and
set the level of at least one of the first and second erase permission voltages as the default level when the level of at least one of the first and second erase voltages is lower than an expected level.

8. The memory device of claim 5, wherein the control circuit comprises:
a peripheral circuit configured to perform the first or second erase progress operation of applying one of the plurality of erase voltages to the substrate and the first or second erase verification operation of checking the erase state of the first or second sub-block by applying an erase verification voltage to the first or second word line, in a state in which the first or second erase permission voltage and an erase prevention voltage are applied to the first or second word line; and
control logic configured to:
control the peripheral circuit to perform an operation of checking the level of the first erase voltage by alternately performing the first erase progress operation and the first erase verification operation on the first sub-block of the selected memory block in the first operation mode and an operation of checking the level of the second erase voltage by alternately performing the second erase progress operation and the second erase verification operation on the second sub-block of the selected memory block, and
adjust the levels of the first and second erase permission voltages based on the results of the comparison between the levels of the first and second erase voltages.

9. The memory device of claim 8, wherein the peripheral circuit comprises:
a voltage generator configured to generate the plurality of erase voltages, the first and second erase permission voltages, the erase verification voltage, and the erase prevention voltage;
a row decoder configured to selectively supply the first and second erase permission voltages, the erase verification voltage, and the erase prevention voltage to the plurality of word lines; and
a substrate driver configured to supply one of the plurality of erase voltages to the substrate.

10. The memory device of claim 2, wherein the first operation mode is a mode that is entered and exited when a test operation is started and completed.

11. The memory device of claim 3, wherein the reference word line comprises at least one dummy word line disposed in a middle of the plurality of word lines.

12. An operating method of a memory device including a plurality of memory blocks each including first and second sub-blocks, the operating method comprising:
applying a first erase permission voltage and a first erase voltage among a plurality of erase voltages to a first sub-block of a selected memory block among a plurality of memory blocks, and checking a level of the first erase voltage applied when a verification of an erase state of the first sub-block is successful;
applying a second erase permission voltage and a second erase voltage among the plurality of erase voltages to a second sub-block of the selected memory block and then checking a level of the second erase voltage applied when a verification of an erase state of the second sub-block is successful; and
adjusting levels of the first and second erase permission voltages based on a result of a comparison between the levels of the first and second erase voltages.

13. The operating method of claim 12, further comprising:
in a first operation mode, sequentially performing applying the first erase permission voltage and the first erase voltage, applying the second erase permission voltage and the second erase voltage, and adjusting of the levels of the first and second erase permission voltages; and
in a second operation mode subsequent to the first operation mode, using the first erase permission voltage having the level adjusted in the first operation mode when performing an erase operation on the first sub-block of each of the plurality of memory blocks, and using the second erase permission voltage having the level adjusted in the first operation mode when performing an erase operation on the second sub-block of each of the plurality of memory blocks.

14. The operating method of claim 13, wherein:
each of the plurality of memory blocks comprises a plurality of word lines vertically stacked over a substrate;
a first word line stacked at a first side of a reference word line, among the plurality of word lines, is set as the first sub-block; and
a second word line stacked at a second side of the reference word line is set as the second sub-block.

15. The operating method of claim 14, wherein applying the first erase permission voltage and the first erase voltage comprises:
performing a first erase progress operation of applying one erase voltage among the plurality of erase voltages according to a set sequence, to the substrate, in a state in which the first erase permission voltage having a default level is applied to the first word line of the selected memory block;
performing a first erase verification operation of verifying an erase state of the first sub-block by applying an erase verification voltage to the first word line after the first erase progress operation; and
alternately performing the first erase progress operation and the first erase verification operation, and setting, as the first erase voltage, a voltage applied to the substrate in the first erase progress operation performed before the verification of the erase state is successful.

16. The operating method of claim 15, wherein applying the second erase permission voltage and the second erase voltage comprises:
performing a second erase progress operation of applying one voltage among the plurality of erase voltages according to a set sequence, to the substrate, in a state in which the second erase permission voltage having the default level is applied to the second word line of the selected memory block;
performing a second erase verification operation of verifying an erase state of the second sub-block by applying an erase verification voltage to the second word line after the second erase progress operation; and
alternately performing the second erase progress operation and the second erase verification operation, and setting, as the second erase voltage, an erase voltage applied to the substrate in the second erase progress operation performed before the verification of the erase state is successful.

17. The operating method of claim 16, wherein adjusting the levels of the first and second erase permission voltages comprises:
setting the level of the second erase permission voltage to be higher than the level of the first erase permission voltage when the level of the first erase voltage is higher than the level of the second erase voltage;
setting the level of the first erase permission voltage to be higher than the level of the second erase permission voltage when the level of the second erase voltage is higher than the level of the first erase voltage; and
setting the level of the first erase permission voltage and the level of the first erase permission voltage to be identical with each other when the level of the first erase voltage and the level of the second erase voltage are identical with each other.

18. The operating method of claim 17, wherein adjusting the levels of the first and second erase permission voltages comprises:
setting the level of each of the first and second erase permission voltages to be higher than the default level when each of the levels of the first and second erase voltages is higher than an expected level; and
setting the level of at least one of the first and second erase permission voltages as the default level when the level of at least one of the first and second erase voltages is lower than the expected level.

19. The operating method of claim 13, wherein the first operation mode is a mode that is entered and exited when a test operation is started and completed.

20. The operating method of claim 14, wherein the reference word line comprises at least one dummy word line disposed in a middle of the plurality of word lines.
